(19) United States
(12) Patent Application Publication
(10) Pub. No.: US 2025/0125766 A1
(43) Pub. Date: Apr. 17, 2025

(54) FRAMELESS, BACKRAIL-SUPPORTED SOLAR MODULE AND INSTALLATION METHODS

(71) Applicant: Maxeon Solar Pte. Ltd., Singapore (SG)

(72) Inventors: Edwin Alexander Peraza Hernandez, San Jose, CA (US); Yafu Lin, Pleasanton, CA (US); Zhaoji Li, Fremont, CA (US); Nicholas Berry, Beaverton, OR (US)

(73) Assignee: Maxeon Solar Pte. Ltd., Singapore (SG)

(21) Appl. No.: 18/887,585

(22) Filed: Sep. 17, 2024

Related U.S. Application Data
(60) Provisional application No. 63/544,318, filed on Oct. 16, 2023.

(51) Int. Cl. H02S 40/10; F16B 7/04; H01L 31/048; H02S 20/32

(52) U.S. Cl. CPC H02S 40/10; F16B 7/0493; H02S 20/32; H10F 19/807

(57) ABSTRACT

A bifacial solar module is described. The bifacial module has a laminate with a sun-facing glass layer and a backside glass layer, and two backrails attached to the backside glass layer for structural support. The bifacial module has an array of solar cells within a laminate, and the laminate has exterior edges that are not in contact with a frame structure or clamps. Two bifacial modules may be combined in a space-saving solar panel packaging arrangement. Also described is a solar panel assembly, which includes a mounting system configured to attach the bifacial module to a torque tube of a tracking system.

### CROSS-REFERENCE TO RELATED APPLICATION

This application claims the benefit of U.S. Provisional Patent Application No. 63/544,318, filed Oct. 16, 2023, which is incorporated by reference herein in its entirety.

### TECHNICAL FIELD

The present invention relates to a solar panel and a mounting system for the solar panel.

### BACKGROUND

Solar cells, also known as photovoltaic cells, are semiconductors that convert light or solar radiation directly to electricity. They may be encapsulated in a laminate and form a solar module or solar panel.

Photovoltaic energy conversion provides an environmentally friendly means to generate electricity. Given the increasing interest in reducing the costs of renewable energy, the development of more cost-effective solar panels has gained increased attention.

Various solar module fixation technologies are commercially available today. In order to fix a solar module, a well-designed module supporting structure is required. This not only sustains the weight of the module, but also provides fixation points that are mechanically resilient against wind and snow environmental loads. In most cases, a solar module is mounted in an inclined position, and the solar module typically includes a frame support that comprises aluminum and surrounds the entire perimeter of the module laminate. In power plant installations of solar modules, the frame support may attach to a torque tube of a tracker system or a fixed angle installation. However, the high frame volumes involved, along with the rapidly increasing costs of aluminum, (which is the most commonly used material for solar module frames) can result in more expensive installations than installations that use other readily available structural materials.

Some solar modules, known as bifacial modules, are designed to accept light from both the front and the rear sides of the solar modules. In conventional bifacial modules, both the front and the rear layers of the module laminate should be optically transparent.

Furthermore, the frame support overlaps the edge of the laminate comprising the solar cells. This overlap causes a reduction in the sunlight received by the front and rear faces of the solar cells as compared to a frameless design. Similarly, the frame support includes a catch where snow, dirt, and other debris easily accumulate, further shading the solar cells along the edges of the laminate.

### SUMMARY

A solar panel having a bifacial laminate having an array of encapsulated solar cells, a sun-facing glass layer, a backside glass layer, and two backrails attached to the backside glass layer is disclosed. No exterior edge of the bifacial laminate is in contact with a frame structure or clamps, and the length of each backrail is substantially parallel to the length of the bifacial laminate.

In one embodiment, the bifacial laminate is substantially rectangular and has a length longer than its width.

In one embodiment, a length of the bifacial laminate is in a range of 1.8 to 2.6 m and a width is in a range of 0.9 to 1.5 m.

In one embodiment, a length of the backrails is in a range of 75% to 110% of the length of the bifacial laminate. The backrails may not necessarily have to extend along the full length of the laminate to provide structural support, allowing for material savings. On the other hand, the backrails can extend beyond the edges of the laminate if mounting along the short side is required.

In one embodiment, the bifacial laminate has at least three strings of cells aligned parallel to its length. Each adjacent two strings of cells are spaced from each other by a gap, and each backrail is located on the two gaps that are the farthest apart from each other.

In one embodiment, the two backrails may comprise galvanized steel, stainless steel, or steel with an anti-corrosive coating. The two backrails can also comprise other structural materials including, but not limited to, aluminum, aluminum alloy, and polymer-matrix composites. The materials or coatings utilized for the backrails must be selected such that the backrails do not develop degradation (e.g., red corrosion rust) during the expected life of the solar panel.

In one embodiment, the two backrails each have a flat top surface and a flat bottom surface. The flat top surface and the flat bottom surface lie in substantially parallel planes.

In a further embodiment, the shortest distance between the flat top surface and the flat bottom surface is in a range of 20 to 80 mm.

In one embodiment, the backrails have a wall thickness in a range of 0.5 to 3.0 mm.

In one embodiment, the two backrails have uniform cross-sections along their entire length.

In one embodiment, the two backrails are each attached to the backside glass layer by an adhesive compound in contact with the flat top surface.

In a further embodiment, the adhesive compound is a silicone-based compound.

In a further embodiment, a portion of the backside glass layer in contact with the adhesive compound comprises a textured glass surface for stronger adhesion.

In one embodiment, the flat bottom surface and the flat top surface each have a width independently in a range of 10 to 100 mm.

In one embodiment, the flat top surface and the flat bottom surface are connected by only one perpendicular wall.

In a further embodiment, the two backrails are each I-beams.

In a further embodiment, the two backrails are each C-beams.

In one embodiment, the flat top surface and the flat bottom surface are connected by two perpendicular walls, forming a tube with a rectangular cross-section.

In one embodiment, the flat top surface and the flat bottom surface are connected by two non-perpendicular walls, forming a tube with a trapezoidal cross-section.

In a further embodiment, a distance between the non-perpendicular walls at the flat top surface is greater than a distance between the non-perpendicular walls at the flat bottom surface.

In a further embodiment, a distance between the non-perpendicular walls at the flat top surface is less than a distance between the non-perpendicular walls at the flat bottom surface.

In one embodiment, the two backrails each have a flat top surface and two flat bottom surfaces. The two flat bottom surfaces define the same plane, and the flat top surface define a plane parallel with the plane defined by the flat bottom surfaces. Each flat bottom surface is connected to the flat top surface by a wall, and the flat bottom surfaces each extend in opposite directions from each other.

In a further embodiment, each wall is perpendicular to both the flat top surface and flat bottom surface.

In a further embodiment, each wall is non-perpendicular to both the flat top surface and flat bottom surface.

In a further embodiment, each of the two backrails is a hat channel.

According to a second aspect, the present invention relates to a solar panel assembly, which includes the solar panel of the first aspect of the invention and a mounting system. The mounting system is in contact with each of the two backrails, and the solar panel assembly is configured to attach to a torque tube.

In one embodiment, the mounting system includes, for each backrail: a drop-on channel and a clamp attached to a bottom of the drop-on channel. The drop-on channel has sides and a flat surface. The flat surface is in contact with a flat bottom surface of the backrail. The clamp is configured to secure around a perimeter of a torque tube.

In a further embodiment, the drop-on channel is secured to the backrail by one or more bolts, pins, clips, and/or rivets.

In a further embodiment, the one or more bolts, pins, clips, and/or rivets traverse through the sides of the drop-on channel and the sidewall(s) of the backrail.

In a further embodiment, the one or more bolts, pins, clips, and/or rivets traverse through the flat surface of the drop-on channel and the flat bottom surface of the backrail.

In a further embodiment, the clamp is secured by a threaded fastener.

In one embodiment, the mounting system includes, for each backrail: a drop-on surface in contact with a flat bottom surface of the backrail, and a clamp attached to a side of the drop-on surface opposing the backrail. The clamp is configured to secure around a perimeter of a torque tube.

In a further embodiment, the drop-on surface is attached to the backrail by one or more bolts, pins, clips, and/or rivets that traverse through the drop-on surface and the flat bottom surface.

In a further embodiment, the drop-on surface is attached to the backrail by a side clamp.

In a further embodiment, the clamp is secured by a threaded fastener.

In one embodiment, the mounting system includes, for each backrail: a slide-in channel and a clamp attached to a bottom side of the slide-in channel. The slide-in channel has a surface in contact with a flat bottom surface of the backrail and a sidewall positioned over the surface. The clamp is configured to secure around a perimeter of a torque tube.

In one embodiment, the mounting system includes, for each backrail: a slide-in channel and a clamp attached to a bottom side of the slide-in channel. The slide-in channel has a surface in contact with a flat bottom surface of the backrail, a stationary sidewall positioned over the surface, and a rotating clamp attached to an edge of the flat bottom surface by a threaded fastener. The clamp is configured to secure around a perimeter of a torque tube. The rotating clamp has a tooth at an end which is inserted into a slot on a sidewall of the backrail. The threaded fastener is configured to provide tension to secure the torque tube at the clamp and to secure the rotating clamp against the sidewall of the backrail.

In a further embodiment, the rotating clamp is elongated in a direction parallel to a central axis of the backrail, forming a wall.

In a further embodiment, the rotating clamp is positioned between two stationary sidewalls.

In a further embodiment, the rotating clamp pivots on a central axis of the threaded fastener.

In one embodiment, the mounting system includes: a clamp configured to secure around a perimeter of a torque tube, the sides of the clamp meeting at a neck near the backrail; two legs extending from the neck; a hook extending from an end of each of the two legs; and a threaded fastener. The legs extend from the neck parallel with the backrails with each leg in contact with a flat bottom surface of the backrails. Each hook is inserted into a slot in the flat bottom surface of the backrail, and the threaded fastener traverses the neck and is configured to provide tension to secure the torque tube at the clamp and to secure the backrail at the hooks.

According to a third aspect, the present invention relates to a solar panel packaging arrangement, comprising a first solar panel and second solar panel of the first aspect, arranged with each backside glass layer facing the other backside glass layer. The first and second solar panels are in contact with each other with the two backside glass layers being substantially parallel, and the distance between the two backside glass layers is less than double the height of any backrail of either solar panel.

In one embodiment, the four backrails are the same size and shape.

In one embodiment, the four backrails each have a flat top surface and a flat bottom surface. The flat top surface and the flat bottom surface define substantially parallel planes, and the flat top surface and the flat bottom surface are connected by only one perpendicular wall.

In a further embodiment, the four backrails are C-beams. The two C-beams of the first solar panel are positioned with their open sides facing one direction, and the two C-beams of the second solar panel are positioned with their open sides facing the opposite direction than the two C-beams of the first solar panel.

In a further embodiment, the flat bottom surface of each backrail sits inside the open side of the backrail of the opposing solar panel.

In a further embodiment, the flat top surface of each backrail comprises a curved or angled projection that extends towards the backside glass layer of the opposing solar panel. The curved or angled projection is configured to prevent the backrails from contacting the backside glass layer of the opposing solar panel.

In one embodiment, each backrail has the perpendicular wall situated with portions of the flat top surface extending on both sides, with one portion of the flat top surface in contact with the flat bottom surface of the backrail of the opposing solar panel.

In one embodiment, the flat top surface and the flat bottom surface of each backrail are connected by two perpendicular walls, forming a tube with a rectangular cross-section. One portion of the flat top surface extends from the tube to form a lip in contact with the flat bottom surface of the backrail of the opposing solar panel.

In a further embodiment, the lip of each backrail has a curved or angled projection that extends towards the backside glass layer of the opposing solar panel. The curved or angled projection is configured to reduce sideways motion of the two solar panels relative to each other.

In one embodiment, the four backrails each have a flat bottom surface with a soft pad adhered thereto, and the soft pad provides cushioning between each backrail and the backside glass layer of the opposing solar panel.

According to a fourth aspect, the present invention relates to a solar panel multipackage, which has two or more solar panel packaging arrangements of the third aspect stacked together.

The foregoing paragraphs have been provided by way of general introduction and are not intended to limit the scope of the following claims. The described embodiments, together with further advantages, will be best understood by reference to the following detailed description taken in conjunction with the accompanying drawings.

### BRIEF DESCRIPTION OF THE DRAWINGS

A more complete appreciation of the disclosure and many of the attendant advantages thereof will be readily obtained as the same becomes better understood by reference to the following detailed description when considered in connection with the accompanying drawings, wherein:

FIG. 1 is a solar panel assembly of a frameless, backrail-supported module according to one embodiment.

FIGS. 2A and 2B are side views of an edge of a prior art solar panel that has a frame and a frame top lip.

FIGS. 3A and 3B are side views of an edge of a frameless, backrail-supported module that does not have a frame or a frame top lip.

FIGS. 4A to 4F are cross-sections of backrails.

FIG. 5 shows the area shaded by the frame of a prior art solar panel having frames on its edges.

FIG. 6 shows the area shaded by the backrails in a solar panel that does not have a frame on its edges and is supported by two backrails.

FIG. 7 is a graph showing the expected ratio of the bifaciality of a bifacial laminate with backrails and a bifacial laminate with a frame.

FIG. 8A is a backrail-supported module mounting system having a drop-on channel and connecting elements placed on the side wall of the channel according to one embodiment.

FIG. 8B is a sideview of FIG. 8A.

FIG. 9A is a backrail-supported module mounting system having a drop-on channel and connecting elements placed on the bottom wall of the channel according to one embodiment.

FIG. 9B is a sideview of FIG. 9A.

FIG. 10A is a backrail-supported module mounting system having a drop-on surface and connecting elements placed on the bottom of the surface according to one embodiment.

FIG. 10B is a sideview of FIG. 10A.

11A is a backrail-supported module mounting system having a drop-on surface and a clamp-like connecting element according to one embodiment.

FIG. 11B is a sideview of FIG. 11A.

FIG. 12A is a backrail-supported module mounting system having a slide-in channel according to one embodiment.

FIG. 12B is a sideview of FIG. 12A.

FIG. 13A is a backrail-supported module mounting system that uses a dual clamp that holds two regions of the backrail according to one embodiment.

FIG. 13B is a bottom view of the backrails of FIG. 13A.

FIG. 14A is a bifacial laminate mounting system that uses a slide-in channel with a rotating clamp according to one embodiment.

FIG. 14B is a side view of FIG. 14A with the rotating clamp open.

FIG. 14C is a side view of FIG. 14A with the rotating clamp closed.

FIG. 15A is a solar panel with C-beam type backrails.

FIG. 15B is a solar panel packaging arrangement made from solar panels similar to those of FIG. 15A according to one embodiment.

FIG. 15C is a solar panel multipackage arrangement made from solar panel packaging arrangements similar to those of FIG. 15B according to one embodiment.

FIG. 16A is a solar panel with C-beam type backrails that have a curved projection from the flat top surface according to one embodiment.

FIG. 16B is a solar panel packaging arrangement made from solar panels of the type in FIG. 16A.

FIG. 17A is a solar panel with C-beam type backrails that have an angled projection from the flat top surface according to one embodiment.

FIG. 17B is a solar panel packaging arrangement made from solar panels of the type in FIG. 17A.

FIG. 18A is a solar panel with rectangular tube type backrails that have an angled projection from the flat top surface according to one embodiment.

FIG. 18B is a solar panel packaging arrangement made from solar panels of the type in FIG. 18A.

FIG. 19A is a solar panel with C-beam type backrails that have an extended portion of the flat top surface according to one embodiment.

FIG. 19B is a solar panel packaging arrangement made from solar panels of the type in FIG. 19A.

FIG. 20 is a solar panel packaging arrangement made from solar panels having a soft pad adhered to the flat bottom surface according to one embodiment.

### DETAILED DESCRIPTION OF THE EMBODIMENTS

Embodiments of the present disclosure will now be described more fully hereinafter with reference to the accompanying drawings, in which some, but not all embodiments of the disclosure are shown.

The present disclosure will be better understood with reference to the following definitions. As used herein, the words “a” and “an” and the like carry the meaning of “one or more,” or “at least one.” Within the description of this disclosure, where a numerical limit or range is stated, the endpoints are included unless stated otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Certain terminology may be used in the following description for the purpose of reference only, and thus are not intended to be limiting. For example, terms such as “upper”, “lower”, “above”, and “below” refer to directions in the drawings to which reference is made. Terms such as “front”, “back”, “rear”, and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import. Similarly, the terms “first”, “second”, and other such numerical terms referring to structures do not imply a sequence or order unless clearly indicated by the context.

As used herein, the words “about,” “approximately,” or “substantially similar” may be used when describing magnitude and/or position to indicate that the value and/or position described is within a reasonable expected range of values and/or positions. For example, a numeric value may have a value that is +/−0.1% of the stated value (or range of values), +/−1% of the stated value (or range of values), +/−2% of the stated value (or range of values), +/−5% of the stated value (or range of values), +/−10% of the stated value (or range of values), +/−15% of the stated value (or range of values), or +/−20% of the stated value (or range of values). Within the description of this disclosure, where a numerical limit or range is stated, the endpoints are included unless stated otherwise. Also, all values and subranges within a numerical limit or range are specifically included as if explicitly written out.

### Solar Panel

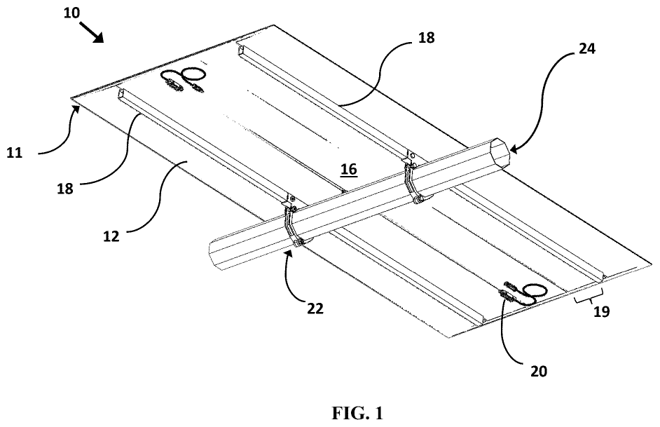

Referring to FIG. 1, in one embodiment, an exemplary solar panel 11 includes a bifacial laminate 12 with a sun-facing glass layer 14 and a backside glass layer 16, and two backrails 18 attached to the backside glass layer 16. The bifacial laminate 12 may also be called a module, or more specifically a frameless, backrail-supported module. The bifacial laminate 12 comprises an array of solar cells positioned between the sun-facing glass layer 14 and the backside glass layer 16. The solar cells are connected to an electrical connection 20, and all exterior edges of the laminate are not in contact with a frame structure or clamps. The length of each backrail is substantially parallel to the length of the bifacial laminate.

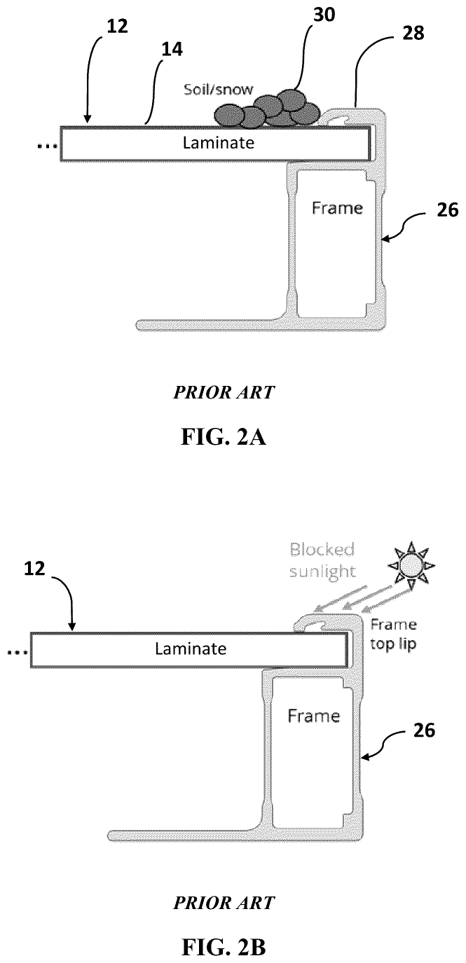

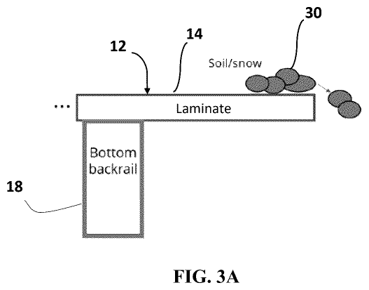

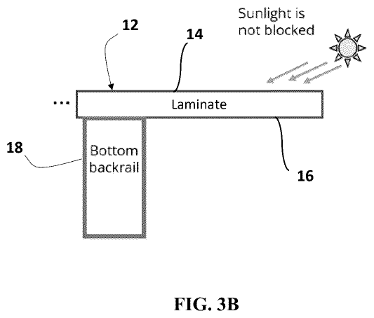

Prior art solar panels, for example, in FIGS. 2A and 2B, have a frame 26 with a top lip 28. Even for a laminated solar panel where the array of solar cells may not abut the edge of the module or laminate, the frame top lip 28 may nevertheless block a portion of the solar cells from exposure to sunlight. In the case of debris 30 such as snow, dirt, and vegetative matter, the frame top lip may provide a catching point for the debris to block even more of the solar cells. In one embodiment, for instance, as shown in FIGS. 3A and 3B, the lack of a frame means that sunlight is not blocked from the edges of the solar panel, and debris may more easily slide off by wind, rain, or gravity. Thus, the use of backrails in place of a frame leads to an improvement in the power generation of the solar panel.

The laminate is for encapsulating the array of solar cells in a substantially flat, weather-tight envelope comprising a laminated construction of various layers including but not limited to glass, encapsulant material (e.g., ethylene-vinyl acetate), active photovoltaic material, interconnecting conductors between solar cells, or a protective backsheet (e.g., polyvinyl fluoride film or glass). In one embodiment, the laminate is a glass-glass laminate. In one embodiment, the laminate has a hydrophobic coating and/or a hydrophilic coating. In a related embodiment, an exterior edge of the laminate is chamfered, beveled, and/or filleted. Each of these embodiments may help snow, dirt, and other debris 30 to slide or fall off the exterior of the bifacial laminate 12 and keep from accumulating.

In one embodiment, the bifacial laminate 12 is rectangular or substantially rectangular and has a length longer than its width, and the length of each backrail 18 is parallel or substantially parallel with the length of the bifacial laminate 12.

In one embodiment, a length of the bifacial laminate 12 is in a range of 1.8 to 2.6 m, 2.0 to 2.5 m, 2.2 to 2.4 mm, 2.3 to 2.4 mm, or about 2.38 mm In other embodiments, the bifacial laminate can have other lengths. In one embodiment, a width of the bifacial laminate 12 is in a range of 0.9 to 1.5 m, or 1.1 to 1.4 m. In other embodiments, the bifacial laminate 12 can have other widths. A thickness of the bifacial laminate 12 may be in a range of 3 to 7 mm. In one embodiment, the thickness of the bifacial laminate 12 may lie within other ranges.

### Backrails

In one embodiment, a length of the backrails 12 may be in a range of 75% to 110%, 80% to 100%, 82% to 97%, or 85% to 95% of the length of the bifacial laminate. In other embodiments, the length of the backrails 12 can be other percentages of the length of the bifacial laminate. The backrails do not necessarily have to extend along the full length of the laminate to provide structural support, allowing for material savings. On the other hand, the backrails can extend beyond the edges of the laminate if mounting along the short side is involved.

In one embodiment, the bifacial laminate 12 may have at least 3 strings of cells, at least 4 strings of cells, or at least 5 strings of cells 19 aligned parallel to its length. In other embodiments, the bifacial laminate 12 may have other numbers of strings of cells that can be aligned parallel to its length. Each adjacent two strings of cells 19 are spaced from each other by a gap 21, and each backrail 18 is attached to the backside glass layer 16 on a gap 21, in order to block the least sunlight from the back side of the cells.

As described, in one embodiment, the bifacial laminate 12 can comprise five strings of cells 19 aligned parallel to its length. Each adjacent two strings of cells 19 are spaced from each other by a gap 21, and each backrail 18 is located on the two gaps 21 that are the farthest apart from each other, for example, as shown in FIG. 6. In one embodiment, each string of cells 19 has the same width as each other string of cells. In another embodiment, each gap 21 has the same width as each other gap.

In one embodiment, the two backrails 18 comprise steel. In other embodiments, the two backrails 18 can include other materials. As defined here, steel is an alloy having 55% to 99.98 wt % of elemental iron and may further comprise carbon, chromium, aluminum, nickel, molybdenum, manganese, vanadium, tungsten, cobalt, titanium, niobium, copper, zirconium, calcium, boron, phosphorus, and/or silicon. In one embodiment, the steel comprises galvanized steel stainless steel, or a steel with an anti-corrosion coating. In still other embodiments, the steel can include other formulations. In one embodiment, the anti-corrosive coating may comprise a zinc, aluminum, or magnesium alloy. In one embodiment, the steel resists corrosion and rusting when located in outdoor environments, and does not develop red rust or damaging corrosion during the expected life of the solar panel.

In one embodiment, the two backrails 18 are not aluminum, or are substantially free of aluminum. In one embodiment, the use of steel in place of aluminum in a solar panel may save on material costs and improve the loading performance of the bifacial laminate.

In one embodiment, the two backrails 18 comprise other structural materials including, but not limited to, aluminum and polymer-matrix composites.

### Backrail Cross-Section Geometry

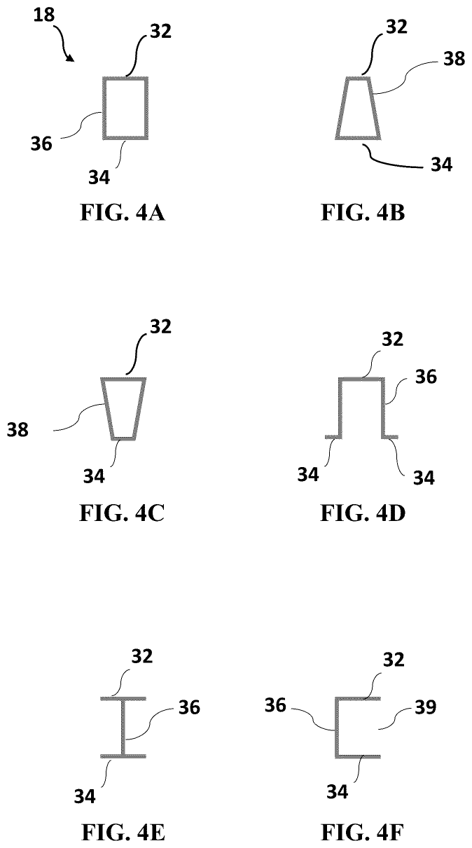

Referring to FIGS. 4A-4F, in one embodiment, the two backrails 18 each have a flat top surface 32 and a flat bottom surface 34. The flat top surface 32 and the flat bottom surface 34 define parallel or substantially parallel planes. The flat top surface 32 and the flat bottom surface 34 may be considered flanges.

In one embodiment, the shortest distance between the flat top surface 32 and the flat bottom surface 34 may be in a range of 20 to 80 mm, 21 to 75 mm, 21 to 70 mm, 22 to 65 mm, 23 to 60 mm, 24 to 55 mm, 25 to 50 mm, 26 to 45 mm, 27 to 40 mm, or 28 to 36 mm. In other embodiments, the shortest distance between the flat top surface 32 and the flat bottom surface may lie within other ranges.

In one embodiment, the backrails 18 may have a wall thickness in a range of 0.5 to 3.0 mm, 0.6 to 2.8 mm, 0.7 to 2.5 mm, 0.8 to 2.2 mm, 0.8 to 2.0 mm, 0.9 to 1.9 mm, 1.0 to 1.8 mm, or 1.2 to 1.7 mm. In other embodiments, the backrails 18 may have a wall thickness that lies within other ranges.

In one embodiment, the two backrails 18 are right prisms, meaning that each one has two bases which are translated copies (rigidly moved without rotation) of one another, with rectangular sides joining corresponding sides of the two bases at right angles.

In one embodiment, the flat bottom surface 34 and the flat top surface 32 may each have a width independently in a range of 10 to 100 mm, 12 to 75 mm, 14 to 50 mm, 16 to 26 mm, 16 to 24 mm, or 18 to 22 mm. In other embodiments, the flat bottom surface 34 and the flat top surface 32 may each have a width that lies within other ranges.

In one embodiment, the flat top surface 32 and the flat bottom surface 34 are connected by only one perpendicular wall 36. The perpendicular wall 36 may be considered a web.

In one embodiment, where there is only one perpendicular wall 36, the backrail 18 is an I-beam, for instance, as shown by the cross-section of the backrail in FIG. 4E.

In one embodiment, where there is only one perpendicular wall 36, the backrail 18 is a C-beam, or a C-channel, for instance, as shown by the cross-section of the backrail in FIG. 4F.

In one embodiment, the flat top surface 32 and the flat bottom surface 34 are connected by two perpendicular walls 36, forming a tube with a rectangular cross-section. One such embodiment is shown in the backrail cross-section of FIG. 4A. In one embodiment, the perpendicular walls 36 have a length longer than the length of the flat bottom surface 34 and the flat top surface 32, as also shown in FIG. 4A. The length of the flat bottom surface 34 may be 30% to 100%, 60% to 85%, or 65% to 80% of the length (i.e., height) of the perpendicular walls 36. In other embodiments, the length of the flat bottom surface 34 can constitute other fractions of the height of the perpendicular walls 36. In one embodiment, the rectangular cross-section is a square cross-section.

In one embodiment, the flat top surface 32 and the flat bottom surface 34 are connected by two non-perpendicular walls 38, forming a tube with a trapezoidal and non-rectangular cross-section. In other words, the flat top surface 32 and the flat bottom surface 34 have unequal widths. In one embodiment, the shorter surface may have a width that is 40 to 95%, 50 to 80%, or 60 to 70% of the width of the longer surface. In other embodiments, the shorter surface may have a width that is other fractions of the width of the longer surface. Cross-sections of these trapezoidal backrails are shown in FIGS. 4B and 4C.

In a further embodiment, a distance between the non-perpendicular walls 38 at the flat top surface 32 is greater than a distance between the non-perpendicular walls 38 at the flat bottom surface 34. In other words, the flat top surface 32 is wider than the flat bottom surface 34. This may be considered an “inverted trapezoid,” as used herein, and an example is shown by the backrail cross-section of FIG. 4C.

In a related embodiment, a distance between the non-perpendicular walls 38 at the flat top surface 32 is less than a distance between the non-perpendicular walls 38 at the flat bottom surface 34. In other words, the flat bottom surface 34 is wider than the flat top surface 32. As used herein, this shape may be considered a “trapezoid” (and not an inverted trapezoid), and an example cross-section of a backrail 18 having such shape is shown in FIG. 4B.

In one embodiment, the two backrails 18 each have a flat top surface 32 and two flat bottom surfaces 34. The two flat bottom surfaces 34 lie in the same plane, and the flat top surface 32 lies in a plane parallel with the plane in which the flat bottom surfaces 34 lie. Each flat bottom surface 34 is connected to the flat top surface 32 by a wall 36/38, and the flat bottom surfaces 34 each extend in opposite directions from each other. In one embodiment, the wall 36/38 may be considered a web, and the flat bottom surfaces 34 may be considered flanges.

In one embodiment, a wall 36 is perpendicular to both the flat top surface 32 and the flat bottom surface 34, for instance, as shown in FIG. 4D.

In one embodiment, a wall 38 is not perpendicular to the flat top surface 32 and the flat bottom surface 34. Instead, the wall 38 may form a smallest angle of at least 100°, at least 110°, or at least 115°, and/or at most 135°, at most 130°, or at most 125°.

In one embodiment, each of the two backrails 18 is a hat channel. An example of a hat channel is shown in the backrail of FIG. 4D.

In one embodiment, additional features may be added to the backrails such as bolt/pin/rivet/clip attachment points, cable management holes, grounding holes, or grooves for adhesion management.

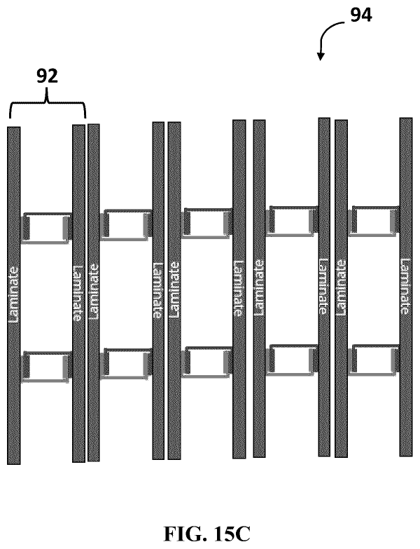

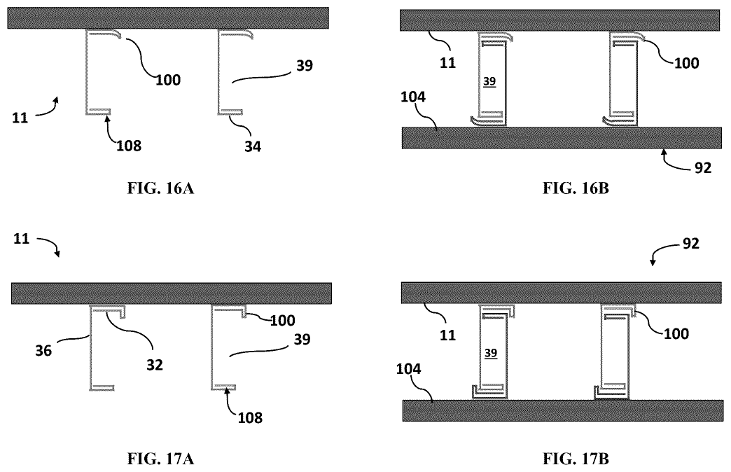

In one embodiment, a portion of the flat top surface 32 may extend along the backside glass layer of the laminate, and may further have a curved or angled projection 100 in a direction away from the backside glass layer. These embodiments are shown in FIGS. 16A-16B, 17A-17B, 18A-B18, and 19A-19B. The flat top surface (or flange) 98 may extend from the perpendicular wall 36 (the web) by a length in a range of 2 to 30 mm. Where the flat top surface 32 has a curved or angled projection 100, the curved or angled projection 100 may have a height in a range of 2 to 5 mm. In one embodiment, the flat top surface 32 may have other lengths and the curved or angled projection 100 may have other heights. The curved or angled projection 100 may be considered a lip.

In one embodiment, any curved or angled projection 100, lip, extended flat top surface 98 (FIG. 19A), or groove extends along the entire length of the backrail. However, in another embodiment, the curved or angled projection 100, lip, extended flat top surface 98, or groove may be located intermittently along the entire length of the backrail. For instance, these projections, grooves, and extended parts may only make up 10% to 90% of the total length of the backrail. For instance, it may not be necessary to have a curved or angled projection 100 along the entire backrail length for the purpose of being able to hook the backrails of opposing solar panels together.

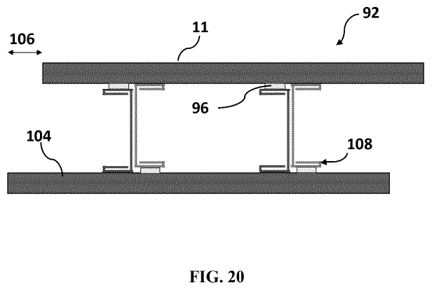

In one embodiment, soft pads 96 may be added to the flat bottom surface of the backrail for packaging purposes, for instance, as shown in FIG. 20. The soft pads 96 may be felt or made of a plastic material that can soften the contact interaction between the backrail of one panel and the laminate glass of the panel packaged with it.

In one embodiment, the soft pads 96 may be made of an elastomeric material, including but not limited to natural rubber, polyisoprene, polybutadiene, chloroprene rubber butyl rubber (copolymer of isobutylene and isoprene), halogenated butyl rubber, styrene-butadiene rubber, nitrile rubber, hydrogenated nitrile rubbers, ethylene propylene rubber, ethylene propylene diene rubber, epichlorohydrin rubber, polyacrylic rubber, silicone rubber, fluorosilicone rubber, fluoroelastomer, perfluoroelastomer, polyether block amides, chlorosulfonated polyethylene, ethylene-vinyl acetate, thermoplastic elastomer, resilin, elastin, polysulfide rubber, elastolefin, and combinations thereof. The soft pad 96 may have a thickness of 0.5 to 5 mm, or 1 to 2 mm. The soft pad 96 may extend the entire length of the backrail or the backrail may have a plurality of separate soft pads 96 along its length.

In one embodiment, the two backrails 18 are each attached to the backside glass layer 16 by an adhesive compound in contact with the flat top surface 32.

In one embodiment, the adhesive compound (or more simply, adhesive) is a silicone-based compound, for instance, room temperature vulcanizing (RTV) silicone. RTV silicone is a type of silicone rubber that cures at room temperature and may be available as one-component or two-component, the two components being a base and a curative. One-part RTV silicones use moisture in the atmosphere to cure from the outside towards the center. The time to cure will decrease with an increase in temperature, humidity, and surface area to volume ratio. Two-part RTV silicones use moisture in the second component as well as a cross-linker such as active alkoxy to cure the silicone in a process called condensation curing. Two-part silicones may also be platinum catalyzed in an addition reaction. Other reactive species to facilitate cross-linking include acetoxy, amine, octoate, and ketoxime. In one embodiment, the RTV silicone is a one-part oxime-type silicone.

In one embodiment, an excess of the adhesive compound on the backside glass layer 16 does not extend further than 2 mm, 1.5 mm, or 1 mm from the flat top surface 32. Decreasing the amount of adhesive on the backside glass layer, along with decreasing the width of the backrails 16 improves bifaciality.

In a further embodiment, a portion of the backside glass layer 16 in contact with the adhesive compound comprises a textured glass surface (for instance, a surface of the laminate being textured by grooves, or roughening) in order to increase adhesive strength. In a related embodiment, the backside glass layer 16 comprises a textured glass surface in order to increase surface area for better heat dissipation. In one embodiment, a surface of the backrail may be textured for better adhesion to the backside glass layer 16. In another embodiment, adhesive tape or other spacers may be used to control the spacing between the backside glass layer 16 and the backrails 18 to improve uniformity of the adhesive thickness.

### Solar Panel Assembly

Referring again to FIG. 1, according to a second aspect, one embodiment relates to a solar panel assembly 10, that includes the solar panel 11 of the first aspect of the invention and a mounting system 22. The mounting system 22 is in contact with each of the two backrails 18, and the solar panel assembly 10 is configured to attach to a torque tube 24. As used herein, the “mounting system” may refer to one or both structures configured to secure the backrails 18 to the torque tube 24. In one embodiment, the torque tube has a shape of a right prism with a base that is a regular octagon. However, in other embodiments, other regular polyhedrons, or circles/ellipses may be used as the base of the torque tube prism shape, such as a square or an equilateral triangle. In one embodiment the torque tube may have a rectangular cross-section that is not a square. In another embodiment, the torque tube 24 may have a cross-section that is non-convex, for instance, the torque tube may be formed with a groove along its length. In one embodiment, the torque tube 24 is part of a tracking system. In other embodiments, the mounting system 22 may be used for attaching a solar panel to a fixed railed configuration.

The method of attaching the solar panel 11 to the torque tube 24 depends on the geometries of the backrails 18 and mounting system 22 used. In some embodiments, such as those using a drop-on channel, drop-on surface, or slide-in channel, the mounting system 22 may first be secured to the torque tube 24 before the solar panel 11 is attached. In other embodiments, such as dual clamp mounting systems 22, the mounting system may be attached to the torque tube 24 and the solar panel 11 at the same time.

In one embodiment, as in the case of a drop-on channel or drop-on surface, the solar panel 11 is placed on top of the mounting system with the backrails 18 in position, and then the backrails are secured to the mounting position by one or more bolt, pin, clip, rivet, clamp, or fastener. In another embodiment, as in the case of a slide-in channel, the solar panel is slid against the mounting system so that the ends of the backrails 18 slide into the channel of the mounting system. The backrails are slid into place on the mounting system, and then secured by one or more bolt, pin, clip, rivet, clamp, or fastener to prevent further sliding.

In one embodiment, the mounting system 22 may comprise steel as in one of the embodiments of steel described above, or may comprise some other metal, including, but not limited to aluminum, titanium, cobalt, tin, and iron, or another material with the strength and corrosion resistance required for the field of application. A length of the mounting system at the backrail (for instance the length of the channel or surface) may be in a range of 100 to 800 cm, 150 to 700 cm, or 200 to 650 cm. In one embodiment, the length of the mounting system at the backrail may lie within other ranges. The separation between the two mounting locations, or the separation between the two backrails, on a single bifacial laminate may be in a range of 300 to 1200 mm.

In one embodiment, the solar panel assembly 10 may have a load rating of at least 2,000 Pa, at least 2,200 Pa, at least 2,400 Pa, at least 2,500 Pa and/or up to 4,000 Pa, up to 3,500 Pa, up to 3,000 Pa based on the strength of the backrails and the size of the mounting system. The load rating may be measured by attaching a solar panel assembly in a fixed center mounting position. The load ratings as described above may be downforce and/or uplift load ratings, also known as snow and wind load ratings, respectively.

As defined here, the load rating is the maximum pressure measured where the bifacial laminate does not begin to crack or have permanent visible deformations, the backrails do not develop permanent visible deformations, and the bifacial laminate does not lose more than 5% of its initial power output. The downforce load rating may be determined by placing weights on the sun-facing glass layer of a bifacial laminate of mounted solar panel assembly, with the sun-facing glass layer facing up. The uplift load rating may be determined by placing weights on the backside glass layer of a bifacial laminate of a mounted solar panel assembly, with the backside glass layer facing up. The power output change and the appearance of cracks in the solar cells of the solar panel assembly from downforce and uplift loads may be measured by electroluminescence (EL) and power measurements of the bifacial laminate before and after applying a load.

Drop-on Channel with Bolt/Pin/Clip/Rivet on the Side

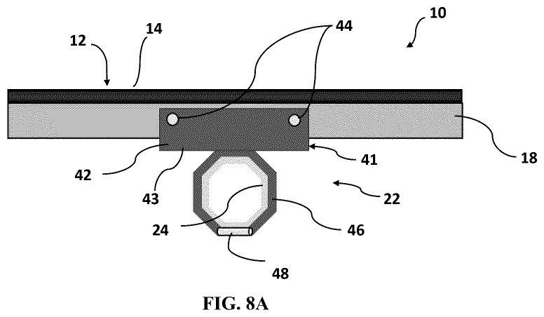

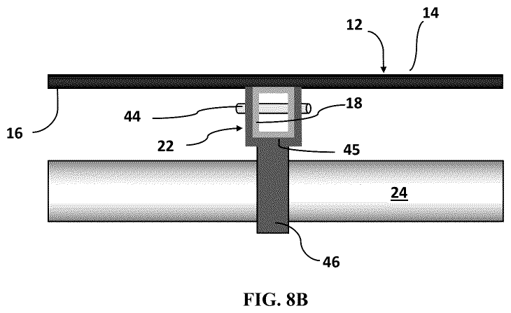

Referring to FIGS. 8A and 8B, in one embodiment, the mounting system 22 includes, for each backrail 18: a drop-on channel 41 and a clamp 46 attached to a bottom 43 of the drop-on channel. The drop-on channel 41 has sides 42 and a flat surface 45. The flat surface 45 is in contact with a flat bottom surface 34 of the backrail 18 and each side 42 is in contact with a sidewall 36/38 of the backrail. The clamp 46 is configured to secure around a perimeter of a torque tube 24. The drop-on channel 41 may be secured to the backrail 18 by one or more bolts, pins, clips, and/or rivets 44. The clamp 46 may be secured by a threaded fastener 48, such as a bolt or a screw. The threaded fastener may have threads all along its length or may have parts that do not have threads.

In a further embodiment, the one or more bolts, pins, clips, and/or rivets traverse through a side of the drop-on channel 42 and a sidewall 36/38 (FIGS. 4A-4F) of the backrail. An example of this mounting system is shown in FIGS. 8A and 8B, where the backrail 18 is a rectangular tube and is secured to the drop-on channel 45 by two bolts 44 through the sides.

The backrail compatibility of this mounting system is summarized in Table 1. Since the drop-on channel requires exterior sidewalls of the backrail that are vertical or have an increasing width towards the bifacial laminate, this mounting system would be compatible with a rectangular tube and inverted trapezoidal tube backrail. It may be fashioned to be compatible with a C-beam backrail, and may not be compatible with a trapezoidal tube, hat channel, or I-beam backrail. This mounting system provides good strength against downforce loads, with the channel walls providing lateral support. The uplift load strength depends on the backrail attachment used.

Drop-on Channel with Pin/Clip/Rivet on the Bottom

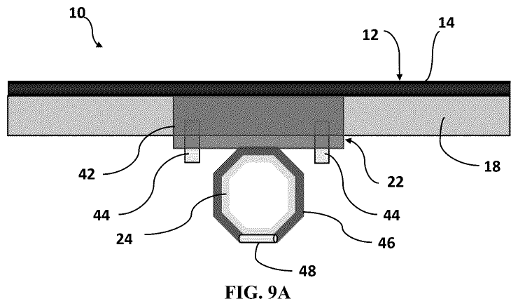

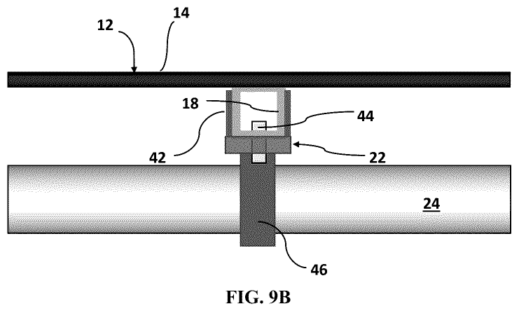

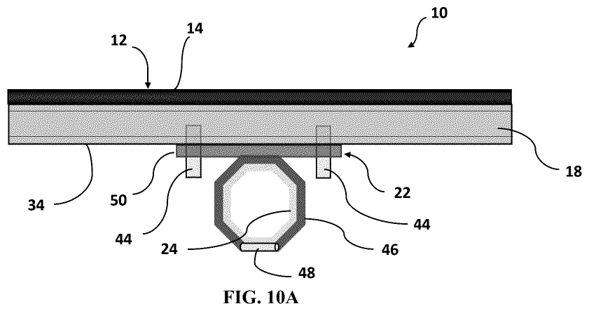

In one embodiment, the mounting system 22 includes, for each backrail 18: a drop-on channel 41 and a clamp 46 attached to a bottom 43 of the drop-on channel. The drop-on channel 41 has sides 42 and a flat surface 45. The flat surface 45 is in contact with a flat bottom surface 34 of the backrail 18 and each side 42 is in contact with a sidewall 36/38 (FIGS. 4E-4F) of the backrail. The clamp 46 is configured to secure around a perimeter of a torque tube 24. The drop-on channel 41 may be secured to the backrail 18 by one or more pins, clips, and/or rivets 44. The clamp 46 may be secured by a threaded fastener 48 (see FIG. 9A as described below), such as a bolt or a screw.

In a further embodiment, the one or more pins, clips, and/or rivets 44 traverses through the flat surface of the drop-on channel 45 and the flat bottom surface 34 of the backrail. Because of this configuration, a bolt may not be possible since the end of the bolt would not be accessible to attach a nut. An example of this mounting system is shown in FIGS. 9A and 9B, where the backrail 18 is a rectangular tube, and is secured to the drop-on channel 45 by two bolts 44 through the bottom.

The backrail compatibility of this mounting system is summarized in Table 1. As before, since the drop-on channel requires exterior sidewalls of the backrail that are vertical or have an increasing width towards the bifacial laminate, this mounting system would be compatible with a rectangular tube and inverted trapezoidal tube backrail. It may be fashioned to be compatible with a C-beam backrail, but may not be compatible with a trapezoidal tube, hat channel, or I-beam backrail. This mounting system provides good strength against downforce loads, with the channel walls providing lateral support. The uplift load strength depends on the backrail attachment used.

Drop-on Surface with Bolt/Pin/Clip/Rivet on the Bottom

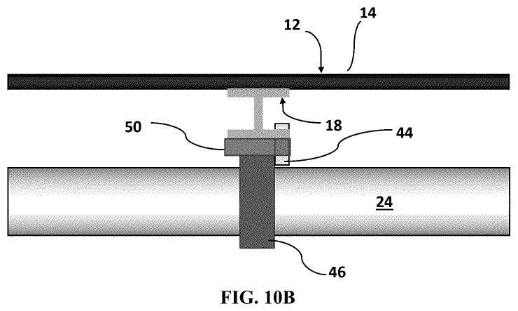

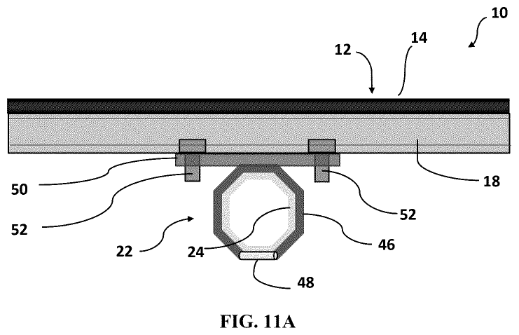

Referring to FIGS. 10A and 10B, in one embodiment, the mounting system 22 includes, for each backrail: a drop-on surface 50 in contact with a flat bottom surface 34 of the backrail 18, and a clamp 46 attached to a side 49 (shown in FIG. 11B) of the drop-on surface opposing the backrail 18. The clamp 46 is configured to secure around a perimeter of a torque tube 24. The clamp 46 may be secured by a threaded fastener 48. The drop-on surface 50 is attached to the backrail 18 by one or more bolts, pins, clips, and/or rivets 44 that each traverse through both the drop-on surface 50 and the flat bottom surface 34. An example of this embodiment is shown in FIGS. 10A and 10B, where the backrail is an I-beam, and the backrail 18 is attached by two bolts 44 to the drop-on surface 50.

This mounting system provides good strength against downforce loads, while the uplift loads depend on the exact attachment used between the backrail and the mounting system. Without lateral walls on the sides of the backrails, the connecting elements must have mechanical resistance against lateral forces and vibrations. However, the lack of lateral walls may reduce material costs and simplify manufacturing. The backrail compatibility of this mounting system is summarized in Table 1. This mounting system is compatible with I-beam and C-beam backrails, though may not be compatible with most hat channels due to the width required to secure the flanges. The mounting system is compatible with the tube-shaped backrails but not if a bolt is used, due to the lack of accessibility to attach a nut.

Drop-on Surface with Side Clamp

Referring to FIGS. 11A and 11B, in one embodiment, the mounting system 22 includes, for each backrail: a drop-on surface 50 in contact with a flat bottom surface 34 of the backrail 18, and a clamp 46 attached to a side 49 of the drop-on surface opposing the backrail 18. The clamp 46 is configured to secure around a perimeter of a torque tube 24. The clamp 46 may be secured by a threaded fastener 48. The drop-on surface 50 is attached to the backrail 18 by a side clamp 52.

In a further embodiment, the drop-on surface 50 has a width greater than a width of the flat bottom surface 34 (see FIGS. 4A-4F) of the backrail 18. In one embodiment, the width of the flat bottom surface 34 may be 50% to 90%, or 60% to 80% of the width of the drop-on surface. In one embodiment, the width of the flat bottom surface 34 may be other percentages of the width of the drop-on surface 50.

FIGS. 11A and 11B show an embodiment of a drop-on surface mounting system with a side clamp 52 and using an I-beam shaped backrail 18. Here, two side clamps are used with the drop-on surface 50, however, it would be possible to use 1, 3, or 4 side clamps with each drop-on surface 50. FIGS. 11A and 11B show the two side clamps on one side of the backrail, however, in other embodiments they may be positioned on opposite sides of the backrail, either directly across from each other or staggered. In one embodiment, the side clamp comprises a threaded fastener, for instance, the side clamp may be a screw or a bolt with a tab washer. Here, the screw or bolt traverses the drop-on surface and a tab washer, and the tab washer presses down on the top of the flat bottom surface 34 of the backrail to hold it in place. In one embodiment, the backrail 18 may have a slot or depression for the side clamp 52 to fit into.

This mounting system provides good strength against downforce loads, while strength against lateral and uplift loads would depend on the type, number, and position of side clamps used. The backrail compatibility of this mounting system is summarized in Table 1. This mounting system is compatible with I-beam, C-beam, and tube backrails. In the case of tube backrails, the tube may have an opening on the sidewall through which the clamp can be inserted. The mounting system may be compatible with the hat channel though the drop-on surface would require an increased width to provide a surface for a side clamp attachment.

Slide-In Channel with Bolt/Pin/Clip/Rivet on the Side

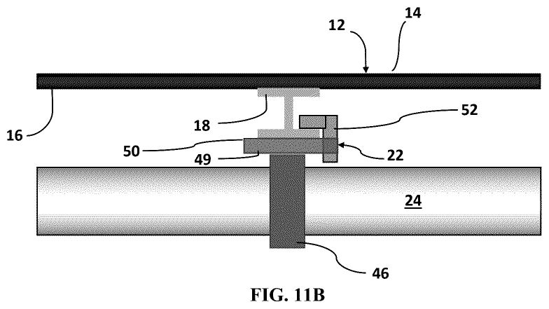

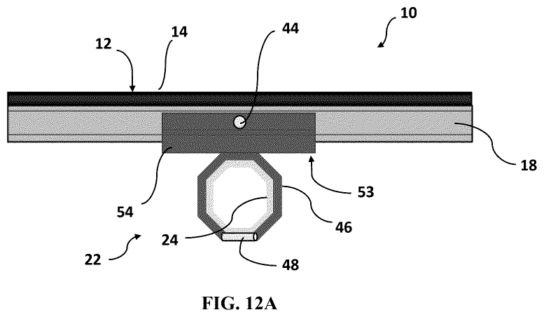

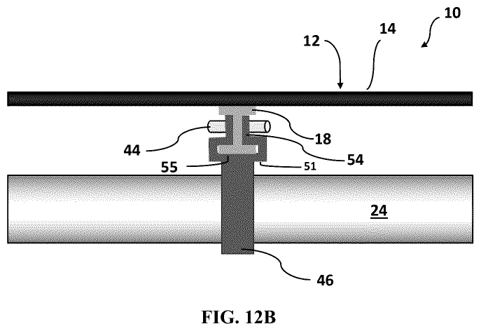

Referring to FIGS. 12A and 12B, in one embodiment, the mounting system 22 includes, for each backrail 18: a slide-in channel 53 and a clamp 46 attached to a bottom side 51 of the slide-in channel 53. The slide-in channel 53 has a surface 55 in contact with a flat bottom surface 34 of the backrail 18 and a sidewall 54 positioned over the surface 55. The clamp 46 is configured to secure around a perimeter of a torque tube 24. The clamp 46 may be secured by a threaded fastener 48.

In one embodiment, the slide-in channel may have two sidewalls from opposite sides of the backrail 18 that are positioned over the surface 55, for instance, as shown in FIG. 12B.

In one embodiment, the slide-in channel 53 is secured to the backrail 18 by one or more bolts, pins, clips, and/or rivets 44 that traverse through the sidewalls 54 and the backrail 18. Alternatively, the slide-in channel could have a bolt/pin/clip/rivet traversing through the bottom side 51 of the slide-in channel, similar to FIG. 9B.

This mounting system is advantageous in that the structure of the slide-in channel provides resistance against lateral, uplift, and downforce loads. The slide-in channel may only require one bolt, pin, clip, and/or rivet to secure a backrail, making its installation in the field faster than the previously described mounting methods that may require the installation of more than one connection element. The backrail compatibility of this mounting system is summarized in Table 1. This design may not be compatible with tube backrails having vertical sidewalls (rectangular tube) or sidewalls with increasing width towards the bifacial laminate (inverted trapezoidal tube). However, this mounting system would be compatible with trapezoidal tube, hat channel, C-beam, and I-beam backrails.

### Combined One Bolt for Torque Tube and Backrail Attachment-Dual Clamp

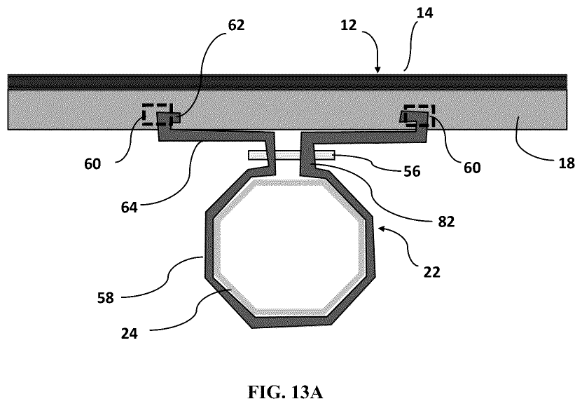

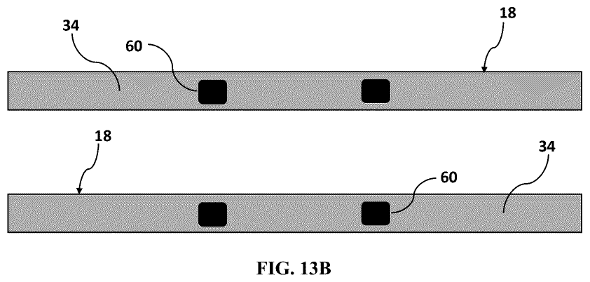

Referring to FIGS. 13A and 13B, in one embodiment, the mounting system 22 includes, for each backrail 18: a clamp 58 configured to secure around a perimeter of a torque tube 24, the sides of the clamp 58 meeting at a neck 82 of the clamp near the backrail 18; two legs 64 extending from the neck 82; a hook 62 extending from an end of each of the two legs 64; and a threaded fastener 56. The legs 64 extend from the neck 82 parallel with the backrails 18 with each leg 64 in contact with a flat bottom surface 34 of the backrails. Each hook 62 is inserted into a slot 60 in the flat bottom surface 34 of the backrail, and the threaded fastener 56 traverses the neck 82 and is configured to provide tension to secure the torque tube 24 at the clamp and to secure the backrail 18 at the hooks 62. FIGS. 13A and 13B show one such embodiment, with a view of the flat bottom surface 34 of the backrails 18 shown in FIG. 13B.

Preferably, this mounting system uses only one threaded fastener 56, though in other embodiments, it may use two or more threaded fasteners 56. In one embodiment, the hooks 62 are rectangular, such as those shown in FIG. 13A, though in other embodiments, the hooks may be curved or angled.

An advantage of this mounting system is that material costs can be reduced significantly as each backrail would require at a minimum one bolt (or threaded fastener) and one clamp with legs. The resistance against forces may vary depending on the design of the structural elements (i.e., the hooks and the amount of force induced by the clamp). The backrail compatibility of this mounting system is summarized in Table 1. This mounting system may be compatible with all backrail designs, with the exception of the hat channel. Without a centrally-located bottom surface, the hat channel may require extra-large flanges in order to provide slots for the hooks.

Slide-In Channel with Clamping Mechanism

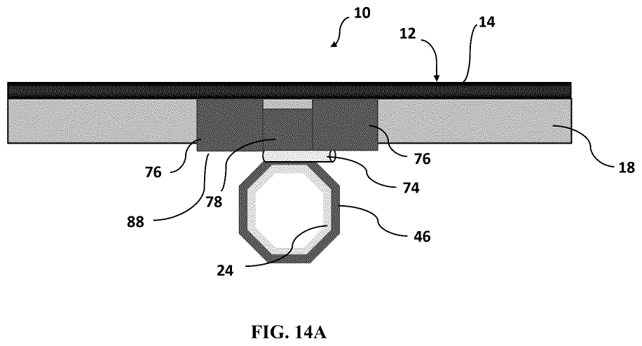

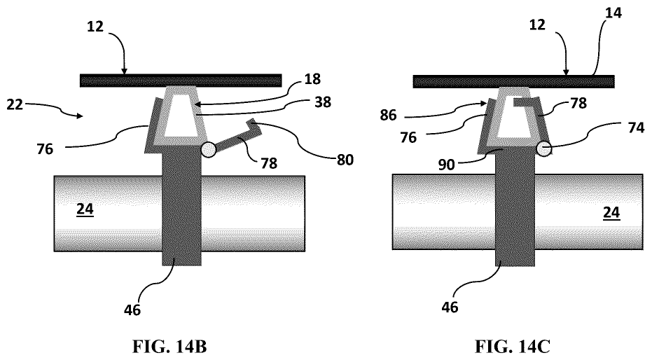

Referring to FIGS. 14A-14C, in one embodiment, the mounting system 22 includes, for each backrail 18: a slide-in channel 86 and a clamp 46 attached to a bottom side 86 of the slide-in channel. The slide-in channel has a surface 90 in contact with a flat bottom surface 34 (see FIGS. 4A-4F) of the backrail, a stationary sidewall 76 positioned over the surface, and a rotating clamp 78 attached to an edge of the flat bottom surface by a threaded fastener 74. The clamp 46 is configured to secure around a perimeter of a torque tube. The rotating clamp 78 has a tooth 80 at an end which is inserted into a slot on a sidewall of the backrail. The threaded fastener 74 is configured to provide tension to secure the torque tube 24 at the clamp 46 and to secure the rotating clamp 78 against the sidewall 36/38 of the backrail. Preferably the rotating clamp 78 pivots on a central axis of the threaded fastener 74.

FIGS. 14A to 14C show one embodiment of the mounting system 22 depicted in FIG. 1. Here, additionally, the rotating clamp 78 is elongated in a direction parallel to a central axis of the backrail 18, forming a wall. The rotating clamp 78 is also positioned between two stationary sidewalls 76.

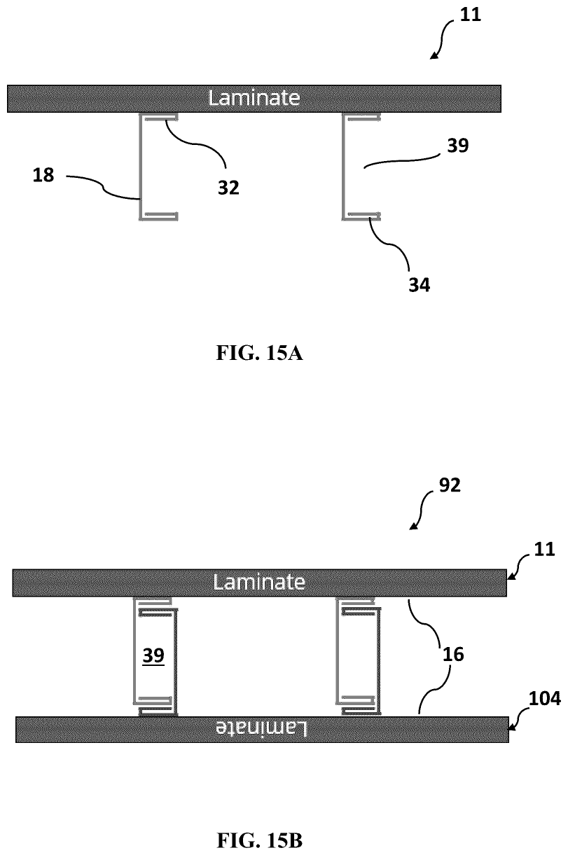

An advantage of this mounting system is that the channel walls keep the backrail in position, providing strong resistance against downforce, uplift, and lateral forces. The rotating clamp is used to prevent the backrail from sliding relative to the slide-in channel. The single threaded fastener or bolt may simplify installation. As indicated in Table 1, this mounting system may be compatible with the trapezoidal tube and the C-beam backrails but may not be compatible with the other backrails (see FIG. 15A).

### Packaging

Referring to FIGS. 15A-FIG. 20, one embodiment relates to a solar panel packaging arrangement 92, comprising a first solar panel 11 and second solar panel 104 of the first aspect, arranged with each backside glass layer 16 facing the other backside glass layer 16 (see FIG. 1). In one embodiment, the first and second solar panels 11/104 are in contact with each other with the two backside glass layers being substantially parallel, and the distance between the two backside glass layers is less than double the height of any backrail 18 of either solar panel. In other embodiments, there can be other distances between the two backside glass layers. The solar panel packaging arrangement 92 enables two solar panels to be combined in a space saving manner, and based on the backrail designs as described below, may further reduce sideways movement, which may further save on packaging material used to restrain movement of the solar panels. The backrails of opposing solar panels may be designed to fit next to each other or to fit within each other.

In one embodiment, the four backrails are the same size and shape. For instance, the four backrails 18 may all be C-beams (C-channels) 108 having the same height and width.

In one embodiment, the four backrails each have a flat top surface 32 and a flat bottom surface 34 (see FIG. 15A). The flat top surface 32 and the flat bottom surface 34 define substantially parallel planes, and the flat top surface 32 and the flat bottom surface 34 are connected by only one perpendicular wall 36.

The four backrails 18 may be C-beams 108, where two C-beams of the first solar panel 11 are positioned with their open sides 39 facing one direction, and the two C-beams of the second solar panel 104 are positioned with their open sides 39 facing the opposite direction than the two C-beams of the first solar panel. In this embodiment backrails do not necessarily have to be bonded to the backside facing opposite directions, but rather the second solar panel may be the same as the first solar panel but rotated in its plane by 180° for packaging.

In a further embodiment, the flat bottom surface 34 of each backrail 18 sits inside the open side 39 of the backrail of the opposing solar panel. An example of this is shown in the solar panel packaging arrangements of FIGS. 15B, 16B, and 17B. Here, the open sides 39 of the C-beams of the first solar panel 11 face the open sides 39 of the C-beams of the second solar panel 104.

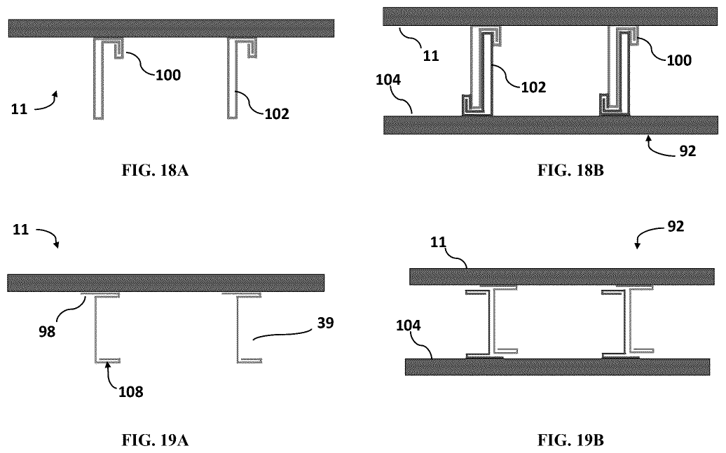

In a further embodiment, the flat top surface 32 of each backrail comprises a curved or angled projection 100 (see FIGS. 16A and 17A) that extends towards the backside glass layer of the opposing solar panel (see FIGS. 16B and 17B). The curved or angled projection 100 is configured to reduce sideways motion of the two solar panels relative to each other, as illustrated in the solar panel packaging arrangements 92 of FIGS. 16B and 17B using C-beams 108 (see FIGS. 16A and 17A). The curved or angled projection 100 may also be configured to prevent the backrails from contacting the backside glass layer of the opposing solar panel. For instance, the curved or angled projection 100 holds the backrails together, or furthermore hooks the backrails together. The curved or angled projections may be used with other backrail geometries, such as I-beam, hat-channel, and rectangular tube. FIG. 18B shows angled projections 100 being used with rectangular tube backrails 102.

In a different embodiment, the two C-beams 108 of the first solar panel 11 are positioned with their open sides 39 facing one direction, and the two C-beams of the second solar panel 104 are positioned with their open sides 39 facing the opposite direction than the two C-beams 108 of the first solar panel 11, but the C-beams do not sit inside their open sides 39. An example of this embodiment is shown in FIG. 20. In this position, the two solar panels may be offset by a length 106 similar to the width of the backrails. For instance, the offset length 106 may be in a range of 2 to 30 mm. Besides C-beam or C-channel backrails, this arrangement may be adapted to work with I-beam, rectangular tube, and hat-channel backrails.

Additionally, in this embodiment, the flat bottom surface 34 of each backrail 18 may contact the backside glass layer 16 of the opposing solar panel (either directly or with a soft pad) or may contact the flat top surface 32 of the opposing backrail.

For instance, where the flat bottom surface 34 of each backrail contacts the flat top surface 32 of the opposing backrail, each backrail has the perpendicular wall situated with portions of the flat top surface extending on both sides, with one portion 98 of the flat top surface 32 in contact with the flat bottom surface 34 of the backrail of the opposing solar panel. This keeps the backrails from directly contacting the backside glass layers of the solar panels. The backrails in this instance may be C-beams, rectangular tubes, I-beams, and hat-channels. FIGS. 18A-18B show this embodiment in the case of C-beam backrails. In an alternative embodiment, the backrails may have a non-perpendicular wall, for instance, in the case of trapezoidal and inverted trapezoidal tubes, situated with portions of the flat top surface 32 extending on both sides, with one portion 98 of the flat top surface 32 in contact with the flat bottom surface 34 of the backrail of the opposing solar panel.

Additionally, where the flat bottom surface 34 of each backrail contacts the backside glass layer 16 of the opposing solar panel, the contact may be direct or may be mitigated with a soft pad 96 to reduce damage to the backside glass layer by abrasion. Thus, in one embodiment, the four backrails each have a flat bottom surface 34 with a soft pad 96 adhered thereto, and the soft pad provides cushioning between each backrail 18 and the backside glass layer 16 of the opposing solar panel. An example of this embodiment is shown in FIG. 20. The soft pad 96 may also be added to other parts of any backrail geometry or to different locations of the backside glass layer 16. Alternatively, rather than a soft pad, the adhesive compound may be extended on the backside glass layer 16 and allowed to cure to provide an area for the backrail of the opposing solar panel to contact without adhering.

According to a fourth aspect, the present invention relates to a solar panel multipackage 94, which has two or more solar panel packaging arrangements 92 of the third aspect stacked together, as shown in FIG. 15C. Here, several solar panels may be packed and shipped together in a space-saving manner. A solar panel multipackage 94 may comprise 2 to 20, preferably 10 to 20 solar panel packaging arrangements 92.

TABLE 1
Mounting system and backrail compatibility

| | | | Inverted |
|---|---|---|---|
| | Rectangular | Trapezoidal | Trapezoidal |
| | tube | tube | tube |
| | [symbol] | [symbol] | [symbol] |
| Drop-on channel + bolt/pin/clip/rivet on the side | Y | N | Y |
| Drop-on channel + pin/clip/rivet on the bottom | Y | N | Y |
| Drop-on surface + bolt/pin/clip/rivet on the bottom | Y, but | Y, but | Y, but |
| | won't work | won't work | won't work |
| | with bolt | with bolt | with bolt |
| Drop-on surface + side clamp | Y | Y | Y |
| Slide-in channel + bolt/pin/clip/rivet on the side | N | Y | N |
| Combined one bolt for torque tube and backrail | Y | Y | Y |
| attachment - dual clamp | | | |
| Slide-in channel with clamping mechanism | N | Y | N |

Y = compatible; N = not compatible

| | Hat channel | I-beam | C-beam |
|---|---|---|---|
| | [symbol] | [symbol] | [symbol] |
| Drop-on channel + bolt/pin/clip/rivet on the side | N | N | N |
| Drop-on channel + pin/clip/rivet on the bottom | N | N | N |
| Drop-on surface + bolt/pin/clip/rivet on the bottom | May be | Y | Y |
| | too wide | | |
| Drop-on surface + side clamp | May be | Y | Y |
| | too wide | | |
| Slide-in channel + bolt/pin/clip/rivet on the side | Y | Y | Y |
| Combined one bolt for torque tube and backrail | May be | Y | Y |
| attachment - dual clamp | too wide | | |
| Slide-in channel with clamping mechanism | N | N | Y |

The examples below are intended to further illustrate the invention without limiting the scope of the claims.

### Example 1

### Backrail Width and Bifaciality

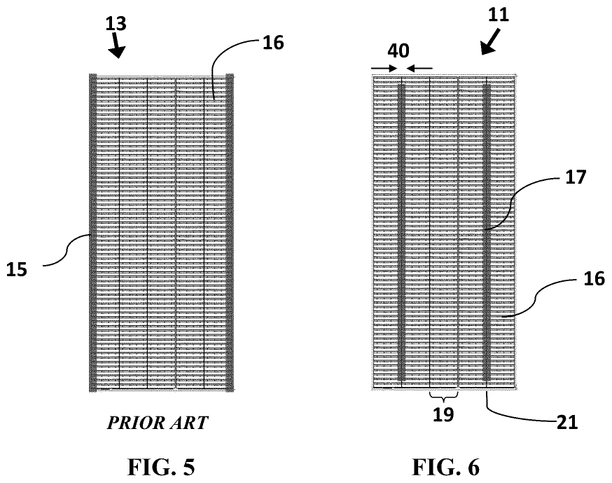

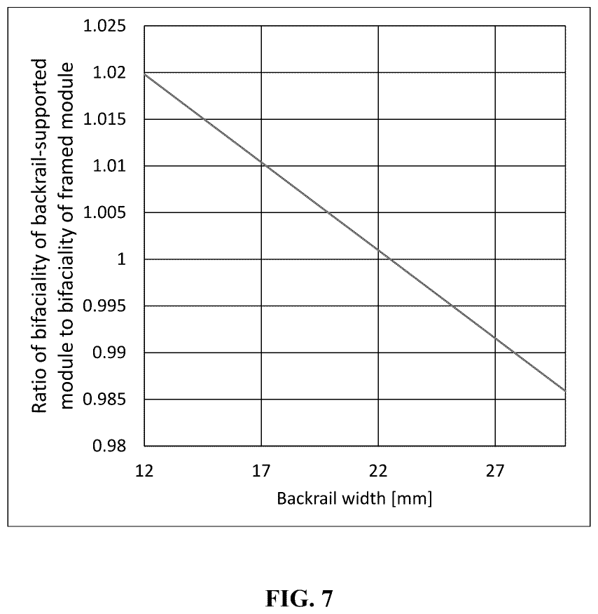

The backrails 18 are centered along a gap 21 between strings of cells 19 as shown in FIG. 6 to reduce the shading on the backside glass layer 16 to cell areas 17 along the backrails. This position compares with the prior art solar panel 13 of FIG. 5, which has a frame structure along its edges, producing a cell area 15 shaded by the frame. FIG. 7 shows modeling data which indicates that if the backrail is designed with a small width, the frameless, backrail-supported module of the present invention can outperform the bifaciality of the prior art framed module.

### Example 2

### Load Testing

Current testing data proved that by using a 2378 mm length×1086 mm width laminate and small rectangular backrails (25.4 mm wide×38.1 mm height×1.65 mm wall thickness) the frameless, backrail-supported module invention can take loads of 2600 Pa downforce and uplift (i.e., snow and wind) with a 200 mm fixed, center mounting configuration using a drop-on channel to attach to the backrail. Here, the solar panel was loaded to 2600 Pa using 101 weights of 15 lbs. (6.8 kg) each which were left on the solar panel for one hour.

Internal testing indicated that no significant power loss was observed in the module under the 2600 Pa load. Also, no cell cracking or visible permanent deformations were observed.

Modeling results for the prior art modules of dimensions length×width of 2378 mm×1086 mm, and 2378 mm×1297 mm, have shown that C-channel backrails can withstand test loads of 2400 Pa downforce and uplift at 200 mm fixed center mounting. Under 500 mm fixed center mounting, the same frameless, backrail-supported module designs have been shown in simulations to meet 3200 Pa downforce and uplift test loads, making them also competitive for regions of high winds. Prior art framed modules have lower downforce and uplift load ratings. For instance, framed modules of similar length and width as the backrail-supported module of this example typically may meet a maximum of 1740 Pa downforce and 1850 Pa uplift loads at a 400 mm fixed, center mounting configuration.

1. A solar panel, comprising:
a bifacial laminate, comprising an array of encapsulated solar cells positioned between a sun-facing glass layer and a backside glass layer; and
two backrails attached to the backside glass layer,
wherein all exterior edges of the bifacial laminate are not in contact with a frame structure or clamps, and
wherein the length of each backrail is substantially parallel to the length of the bifacial laminate.

2. The solar panel of claim 1, wherein a length of the backrails is in a range of 75% to 110% of the length of the bifacial laminate.

3. The solar panel of claim 1, wherein the bifacial laminate comprises three or more strings of cells aligned parallel to its length, each adjacent two strings of cells spaced from each other by a gap, and
wherein each backrail is located on the two gaps that are the farthest apart from each other.

4. The solar panel of claim 1, wherein the two backrails comprise galvanized steel, stainless steel, steel with an anti-corrosive coating, aluminum alloy, or polymer-matrix composite, and wherein the materials or coatings utilized for the backrails are selected such that the backrails do not develop degradation during the expected life of the solar panel.

5. The solar panel of claim 1, wherein the two backrails each have a flat top surface and a flat bottom surface, the flat top surface and the flat bottom surface defining substantially parallel planes.

6. The solar panel of claim 5, wherein the two backrails are right prisms.

7. The solar panel of claim 5, wherein the two backrails are each attached to the backside glass layer by an adhesive compound in contact with the flat top surface.

8. The solar panel of claim 7, wherein the adhesive compound is a silicone-based compound.

9. The solar panel of claim 5, wherein the flat bottom surface and the flat top surface are connected by only one perpendicular wall.

10. The solar panel of claim 9, wherein the two backrails are each I-beams.

11. The solar panel of claim 9, wherein the two backrails are each C-beams.

12. The solar panel of claim 5, wherein the flat top surface and the flat bottom surface are connected by two perpendicular walls, forming a tube with a rectangular cross-section.

13. The solar panel of claim 5, wherein the flat top surface and the flat bottom surface are connected by two non-perpendicular walls, forming a tube with a trapezoidal cross-section.

14. The solar panel of claim 13, wherein a distance between the non-perpendicular walls at the flat top surface is greater than a distance between the non-perpendicular walls at the flat bottom surface.

15. The solar panel of claim 13, wherein a distance between the non-perpendicular walls at the flat top surface is less than a distance between the non-perpendicular walls at the flat bottom surface.

16. The solar panel of claim 1, wherein the two backrails each have a flat top surface and two flat bottom surfaces, the two flat bottom surfaces defining the same plane, the flat top surface defining a plane parallel with the plane defined by the flat bottom surfaces,
wherein each flat bottom surface is connected to the flat top surface by a wall, and the flat bottom surfaces each extend in opposite directions from each other.

17. The solar panel of claim 16, wherein each of the two backrails is a hat channel.

18. A solar panel assembly, comprising:
the solar panel of claim 1, and
a mounting system,
wherein the mounting system is in contact with each of the two backrails, and wherein the solar panel assembly is configured to attach to a torque tube.

19. The solar panel assembly of claim 18, wherein the mounting system comprises, for each backrail:
a drop-on channel comprising sides and a flat surface, wherein the flat surface is in contact with a flat bottom of the backrail, and
a clamp attached to a bottom of the drop-on channel,
wherein the clamp is configured to secure around a perimeter of a torque tube.

20. The solar panel assembly of claim 19, wherein the drop-on channel is secured to the backrail by one or more bolts, pins, clips, and/or rivets.

21. The solar panel assembly of claim 20, wherein the one or more bolts, pins, clips, and/or rivets traverse through the sides of the drop-on channel and one or more sidewalls of the backrail.

22. The solar panel assembly of claim 20, wherein the one or more bolts, pins, clips, and/or rivets traverse through the flat surface of the drop-on channel and the flat bottom surface of the backrail.

23. The solar panel assembly of claim 19, wherein the clamp is secured to the torque tube by a threaded fastener.

24. The solar panel assembly of claim 18, wherein the mounting system comprises, for each backrail:
a drop-on surface in contact with a flat bottom surface of the backrail, and
a clamp attached to a side of the drop-on surface opposing the backrail,
wherein the clamp is configured to secure around a perimeter of a torque tube.

25. The solar panel assembly of claim 24, wherein the drop-on surface is attached to the backrail by one or more bolts, pins, clips, and/or rivets that traverse through the drop-on surface and the flat bottom surface.

26. The solar panel assembly of claim 24, wherein the drop-on surface is attached to the backrail by a side clamp.

27. The solar panel assembly of claim 24, wherein the clamp is secured to the torque tube by a threaded fastener.

28. The solar panel assembly of claim 18, wherein the mounting system comprises, for each backrail:
a slide-in channel, comprising:
a surface in contact with a flat bottom surface of the backrail and
a sidewall positioned over the surface, and
a clamp attached to a bottom side of the slide-in channel,
wherein the clamp is configured to secure around a perimeter of a torque tube.

29. The solar panel assembly of claim 28, wherein the slide-in channel is secured to the backrail by one or more bolts, pins, clips, and/or rivets that traverse through the sidewalls and the backrail.

30. The solar panel assembly of claim 18, wherein the mounting system comprises, for each backrail:
a clamp configured to secure around a perimeter of a torque tube, the sides of the clamp meeting at a neck near the backrail,
two legs extending from the neck,
a hook extending from an end of each of the two legs, and
a threaded fastener,
wherein the legs extend from the neck parallel with the backrails with each leg in contact with a flat bottom surface of the backrail,
wherein each hook is inserted into a slot in the flat bottom surface of the backrail, and
wherein the threaded fastener traverses the neck and is configured to provide tension to secure the torque tube at the clamp and to secure the backrail at the hooks.

31. The solar panel assembly of claim 18, wherein the mounting system comprises, for each backrail:
a slide-in channel, comprising:
a surface in contact with a flat bottom surface of the backrail,
a stationary sidewall positioned over the surface, and
a rotating clamp attached to an edge of the flat bottom surface by a threaded fastener, and
a clamp attached to a bottom side of the slide-in channel,
wherein the clamp is configured to secure around a perimeter of a torque tube,
wherein the rotating clamp has a tooth at an end which is inserted into a slot on a sidewall of the backrail, and
wherein the threaded fastener is configured to provide tension to secure the torque tube at the clamp and to secure the rotating clamp against the sidewall of the backrail.

32. The solar panel assembly of claim 31, wherein the rotating clamp is elongated in a direction parallel to a central axis of the backrail, forming a wall.

33. The solar panel assembly of claim 31, wherein the rotating clamp is positioned between two stationary sidewalls.

34. The solar panel assembly of claim 31, wherein the rotating clamp pivots on a central axis of the threaded fastener.

35. A solar panel packaging arrangement, comprising two of the solar panels of claim 1, including a first solar panel and a second solar panel, arranged with each backside glass layer facing the other backside glass layer,
wherein the first and second solar panels are in contact with each other with the two backside glass layers being substantially parallel, and
wherein the distance between the two backside glass layers is less than double the height of any backrail of either solar panel.

36. The solar panel packaging arrangement of claim 35, wherein the four backrails are the same size and shape.

37. The solar panel packaging arrangement of claim 36, wherein the four backrails each have a flat top surface and a flat bottom surface, the flat top surface and the flat bottom surface defining substantially parallel planes, and
wherein the flat top surface and the flat bottom surface are connected by only one perpendicular wall.

38. The solar panel packaging arrangement of claim 37, wherein the four backrails are C-beams, and
wherein the two C-beams of the first solar panel are positioned with their open sides facing one direction, and the two C-beams of the second solar panel are positioned with their open sides facing the opposite direction than the two C-beams of the first solar panel.

39. The solar panel packaging arrangement of claim 38, wherein the flat bottom surface of each backrail sits inside the open side of the backrail of the opposing solar panel.

40. The solar panel packaging arrangement of claim 39, wherein the flat top surface of each backrail comprises a curved or angled projection that extends towards the backside glass layer of the opposing solar panel, and
wherein the curved or angled projection is configured to reduce sideways motion of the two solar panels relative to each other.

41. The solar panel packaging arrangement of claim 37, wherein each backrail has the perpendicular wall situated with portions of the flat top surface extending on both sides, with one portion of the flat top surface in contact with the flat bottom surface of the backrail of the opposing solar panel.

42. The solar panel packaging arrangement of claim 36, wherein the flat top surface and the flat bottom surface of each backrail are connected by two perpendicular walls, forming a tube with a rectangular cross-section, with one portion of the flat top surface extending from the tube to form a lip in contact with the flat bottom surface of the backrail of the opposing solar panel.

43. The solar panel packaging arrangement of claim 42, wherein the lip of each backrail has a curved or angled projection that extends towards the backside glass layer of the opposing solar panel, and
wherein the curved or angled projection is configured to prevent the backrails from contacting the backside glass layer of the opposing solar panel.

44. The solar panel packaging arrangement of claim 36, wherein the four backrails each have a flat bottom surface with a soft pad adhered thereto, and
wherein the soft pad provides cushioning between each backrail and the backside glass layer of the opposing solar panel.

45. A solar panel multipackage, comprising two or more solar panel packaging arrangements of claim 35 stacked together.
